(19) United States
(12) Patent Application Publication
(10) Pub. No.: US 2007/0077704 A1
(43) Pub. Date: Apr. 5, 2007

(54) METHOD OF FABRICATING A BOTTLE-SHAPED TRENCH

(76) Inventor: Tsai-Chiang Nieh, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,896

(22) Filed: Nov. 3, 2005

(30) Foreign Application Priority Data
Oct. 4, 2005 (TW) 94134631

(51) Int. Cl. H01L 21/20; H01L 21/8242

(52) U.S. Cl. 438/246; 438/386; 438/389; 438/398

(57) ABSTRACT

A method of fabricating a bottle-shaped trench is described. A substrate having a deep trench is provided. A conformal silicon material layer is formed on the substrate. A photoresist layer is formed in the deep trench to cover a portion of the silicon material layer. An ion implantation process is performed to make the silicon material layer divided into a doped silicon material layer and an un-doped silicon material layer. The photoresist layer is then removed. The un-doped silicon material layer is removed to expose a portion of the substrate in the trench, wherein the removing rate of the un-doped silicon material layer is greater than that of the removing rate of the doped silicon material layer. A portion of the substrate exposed in the trench is removed.

### CROSS-REFERENCE TO RELATED APPLICATION

This application claims the priority benefit of Taiwan application serial no. 94134631, filed on Oct. 04, 2005. All disclosure of the Taiwan application is incorporated herein by reference.

### BACKGROUND OF THE INVENTION

1. Field of Invention

The present invention relates to a method for fabricating a trench. More particularly, the present invention relates to a method for fabricating a bottle-shaped trench.

2. Description of Related Art

As IC technology is scaled into the deep sub-micron the device size is gradually reduced. For the structure of the conventional dynamic random access memory (DRAM), it also means that the capacitors in a unit area of the substrate surface are required compacted. On the other hand, since the size of the computer application program gradually become large, the high capacitance for one memory cell should be desirably achieved, accordingly. In the situation that the occupied area of the capacitor becomes smaller and the memory capacitance becomes larger, it indicates that the fabrication process for the capacitor of DRAM is necessary to be changed, so as to satisfy the requirement in trend.

The structure of DRAM capacitor is mainly divided into two types: one is stack capacitor; and the other one is deep trench capacitor. Under the requirement in reducing the size of semiconductor device, both the stack capacitor and the deep trench capacitor have encountered more and more difficulty in fabrication technology.

Taking the deep trench capacitor in consideration, if the capacitance of the capacitor is intended to increase under the limited available space, it can be achieved by increasing the surface area of the electrodes in contact with the capacitor dielectric layer therebetween. Therefore, a structure of bottle-shaped deep trench is applied to the deep trench capacitor. The structure of bottle-shaped deep trench can increase surface area without increasing the occupied area on the substrate surface for the embedded-type electrode, so as to increase the capacitance of the capacitor.

However, since the conventional fabrication process for the bottle-shaped deep trench needs several steps to accomplish the bottle-shaped deep trench. This causes the whole fabrication flow to accomplish the capacitor with the bottle-shaped deep trench is too tedious and complicate, resulting in the increase of cost, and losing competition in the market.

### SUMMARY OF THE INVENTION

The invention provides a method of fabricating a bottle-shaped trench with reduce complicity in fabrication process.

The invention provides a method of fabricating a bottle-shaped trench, capable of effectively increasing the capacitance.

The invention provides a method of fabricating a bottle-shaped trench, including providing a substrate having a deep trench being formed. A silicon material layer is conformally formed over the substrate. A masking layer is formed in the deep trench, and the masking layer covers a portion of the silicon material layer. An ion implanting process is performed on the other portion of the silicon material layer, not being covered by the masking layer. As a result, the silicon material layer is divided into a doped silicon material layer and an un-doped silicon material layer. The masking layer is removed. The un-doped silicon material layer is removed to expose a portion of the substrate within the deep trench, wherein a removing rate for the un-doped silicon material layer is larger than a removing rate for the doped silicon material layer. A portion of the substrate being exposed within the deep trench is removed.

According to an embodiment of the invention, in the foregoing method of fabricating a bottle-shaped trench, the ion implanting process includes a tilt-angle ion implanting process.

According to an embodiment of the invention, in the foregoing method of fabricating a bottle-shaped trench, the tilt angle for the ion implanting process is 2-4 degrees, deviating from the normal line of the substrate surface.

According to an embodiment of the invention, in the foregoing method of fabricating a bottle-shaped trench, the ions used in the ion implanting process are boron ions or BF₂ ions.

According to an embodiment of the invention, in the foregoing method of fabricating a bottle-shaped trench, the implanting energy used in the ion implanting process is 1 KeV-10 KeV.

According to an embodiment of the invention, in the foregoing method of fabricating a bottle-shaped trench, the dopant dosage in the ion implanting process is 1×10¹³/cm²-1×10¹⁷/cm².

According to an embodiment of the invention, in the foregoing method of fabricating a bottle-shaped trench, the process for removing the un-doped silicon material layer includes wet etching. The etchant used in the wet etching process preferably is diluted ammonia.

According to an embodiment of the invention, in the foregoing method of fabricating a bottle-shaped trench, the process to remove the portion of the substrate being exposed within the deep trench includes wet etching. The etchant used in the wet etching process preferably is ammonia.

According to an embodiment of the invention, in the foregoing method of fabricating a bottle-shaped trench, the silicon material is amorphous silicon or polysilicon.

The invention provides a method of fabricating a bottle-shaped trench, including providing a substrate having a deep trench being formed. A conformal etching stop layer is formed over the substrate. A conformal silicon material layer is formed over the etching stop layer. A masking layer is formed in the deep trench, and the masking layer covers a portion of the silicon material layer. An ion implanting process is performed on the other portion of the silicon material layer, not being covered by the masking layer. As a result, the silicon material layer is divided into a doped silicon material layer and an un-doped silicon material layer. The masking layer is removed. The un-doped silicon material layer is etched by using the etching stop layer as an etching stop position. An etching rate for the un-doped silicon material layer is larger than an etching rate for the doped silicon material layer. The exposed portion of the etching stop layer within the deep trench is removed. A portion of the substrate being exposed within the deep trench is removed.

According to an embodiment of the invention, the foregoing method of fabricating a bottle-shaped trench further includes performing an oxidation process on the doped silicon material layer after etching the un-doped silicon material layer, so that the doped silicon material layer becomes a silicon oxide layer. Preferably, after the portion of the substrate being exposed within the deep trench is removed, the method further includes forming a hemispherical grain silicon (HSG-Si) layer on the exposed portion of the substrate.

According to an embodiment of the invention, in the foregoing method of fabricating a bottle-shaped trench, the method for forming the HSG-Si layer on the exposed portion of the substrate is first forming a conformal HSG-Si layer over the substrate, and then performing an etching back process to remove a portion of the HSG-Si layer at the surface of the silicon oxide.

In the method of fabricating a bottle-shaped trench of the invention, since the removing rate of the silicon material layer is changed, it can be achieved to selectively remove the silicon material layer.

In addition, the fabrication complication for the method of fabricating a bottle-shaped trench in the invention can be reduced, and then the fabrication processes can be effectively reduced, the fabrication time can be improved, and the fabrication cost can be reduced.

In addition, the method of fabricating a bottle-shaped trench of the invention can increase the surface area for the bottle-shaped trench being formed, and therefore increase the capacitance of the capacitor.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1B are cross-sectional views, schematically illustrating the process for removing materials over a semiconductor substrate.

FIGS. 2A-2C are cross-sectional views, schematically illustrating a method of fabricating a bottle-shaped trench, according to an embodiment of the invention.

FIGS. 3A-3D are cross-sectional views, schematically illustrating a method of fabricating a bottle-shaped trench, according to another embodiment of the invention.

### DESCRIPTION OF THE PREFERRED EMBODIMENTS

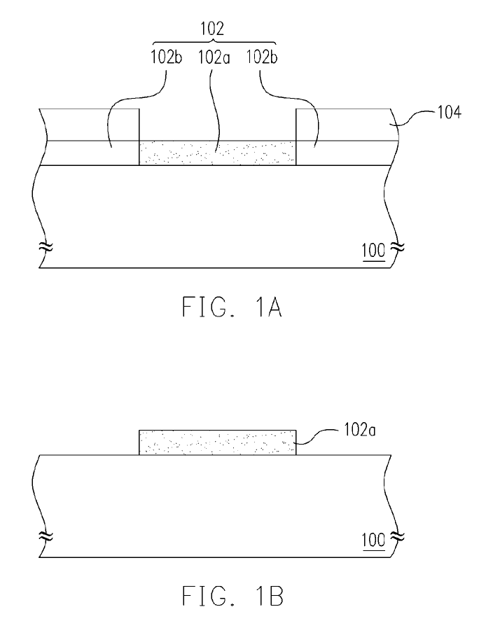

FIGS. 1A-1B are cross-sectional views, schematically illustrating the process for removing materials from a semiconductor substrate.

First, referring to FIG. 1A, a substrate 100 is provided. The substrate 100 is, for example, a silicon substrate.

Then, a silicon material layer 102 is formed over the substrate 100. The material for the silicon material layer 102 can be, for example, amorphous silicon or polysilicon. The process to form the silicon material layer 102 includes, for example, chemical vapor deposition.

Then, a patterned masking layer 104 is formed on the silicon material layer 102. The patterned masking layer 104 is, for example, the patterned photoresist layer, and the material for the patterned photoresist layer is, for example, polymer. The process to form the patterned masking layer 104 includes, for example, performing a photolithographic process.

An ion implantation process is performed on the silicon material layer 102, at a portion not being covered by the patterned masking layer 104. The silicon material layer 102 can then be divided into a doped silicon material layer 102a and an un-doped silicon material layer 102b. The ions used in the ion implantation process are for example, B ions or BF₂ ions.

In FIG. 1B, the patterned masking layer 104 is removed. The un-doped silicon material layer 102b is removed, wherein a removing rate on the un-doped silicon material layer 102b is greater than the removing rate on the doped silicon material layer 102a. The process to remove the un-doped silicon material layer 102b includes, for example, wet etching. The wet etching uses the liquid etchant, such as the diluted ammonia.

As described in the foregoing embodiment, by performing the ion implantation on the silicon material layer 102, the removing rate on the silicon material layer 102 can be changed, so that the removing rate on the un-doped silicon material layer 102b is greater than the removing rate on the doped silicon material layer 102a. As a result, the selective removing function can be achieved.

According to the foregoing descriptions, some experiments with the experimental data are shown, so as to verify the effect that the removing rate on the un-doped silicon material layer 102b is greater than the removing rate on the doped silicon material layer 102a. The experiment can use the polysilicon material as the silicon material. The BF₂ ions are used as the dopants to perform the ion implantation process on the polysilicon. The implanting energy is, for example, 5 KeV.

If the dosage of dopants in the ion implantation process is 1×10¹⁴ 1/cm²-1×10¹⁵ 1/cm², the wet etching with the diluted ammonia for removing the doped polysilicon material has the etching rate of about 1.55-2.3 angstroms/min while the diluted ammonia for removing the un-doped polysilicon material has the etching rate of about 70 angstroms/min. As a result, the removing rate on the un-doped polysilicon material layer 102b is greater than that on the doped polysilicon material layer. In addition, if the dopant concentration of the doped polysilicon material layer is higher, the removing rate on the doped polysilicon material layer is lower.

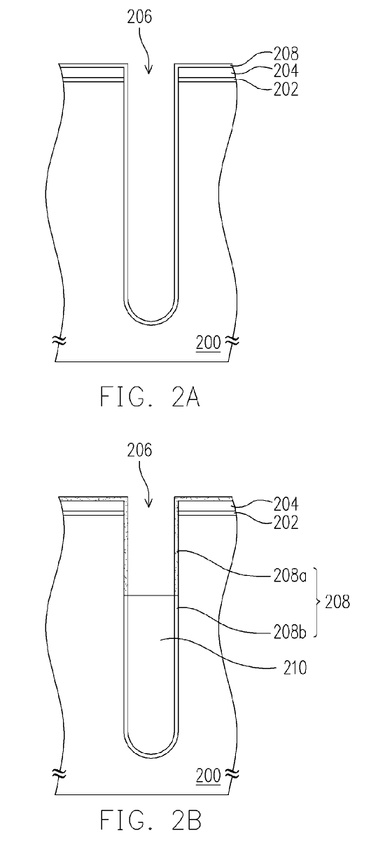

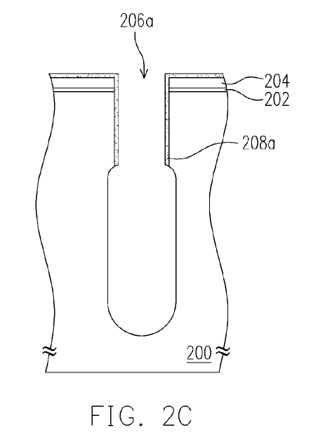

FIGS. 2A-2C are cross-sectional views, schematically illustrating a method of fabricating a bottle-shaped trench, according to an embodiment of the invention.

First, referring to FIG. 2A, a substrate 200 is provided. The substrate 200 has a deep trench 206, having already been formed. The substrate 200 is, for example, silicon substrate. The deep trench has a depth of, for example, 6-8 microns. The process to form the deep trench 206 includes, for example, sequentially forming a pad oxide layer 202 and a hard mask layer 204 over the substrate 200 in a pattern. The patterned pad oxide layer 202 and the patterned hard mask layer 204 are used as an etching mask to perform a dry etching process. The hard masking layer 204 is, for example, silicon nitride.

A conformal silicon material layer 208 is formed over substrate 200 with a thickness of, for example, 20-30 nm. The material for the silicon material layer 208 can be, for example, amorphous silicon or polysilicon. The process to form the silicon material layer 208 includes, for example, chemical vapor deposition.

Referring to FIG. 2B, a masking layer, such as a photoresist layer 210, is formed in the deep trench 206. The photoresist layer 210 covers the silicon material layer 208 at bottom of the deep trench 206. The process to form the photoresist layer 210 in the deep trench 206 is, for example, performing a spin coating process over the substrate to form a photoresist layer (not shown in FIG. 2B). Then, a dry etching process is performed to remove a portion of the photoresist layer. In addition, after forming the photoresist layer and before etching the photoresist layer, a planarization process can be further performed on the photoresist layer.

Then, the exposed portion of the silicon material layer 208, not covered by the photoresist layer 210, is performed with an ion implantation process, so that the silicon material layer 208 is divided into a doped silicon material layer 208a and an un-doped silicon material layer 208b. The ion implantation process is, for example, a tilt-angle ion implantation process. The tilt angle for the tilt-angle ion implantation process is, for example, 2-4 degrees, deviating from the normal line of the substrate surface. The preferred implantation angle can be determined, according to a depth of the silicon material layer 208 to be implanted at the portion not being covered by the photoresist layer 210 and the dimension of the opening of the deep trench 206. The ions used in the ion implantation process can include, for example, B ions or BF₂ ions. The implantation energy of the implantation process is, for example, 1 KeV-10 Kev, preferably 5 KeV. The dopant dosage for the ions in the ion implantation process can be, for example, 1×10¹³ 1/cm²-1×10¹⁷ 1/cm², and preferably 1×10¹⁵ 1/cm².

In FIG. 2C, the photoresist layer 210 is removed. The process to remove the photoresist layer 210 is, for example, a wet etching process. The inorganic solution used in the removing the photoresist layer 210 is, for example, sulfuric acid with H₂O₂ and H₂O, or the sulfuric acid with ozone and H₂O.

The un-doped silicon material layer 208b is removed and a portion of the substrate 200 within the deep trench 206 is exposed. The removing rate on the un-doped silicon material layer 208b is greater than the removing rate on the doped silicon material layer 208a. The process for removing the un-doped silicon material layer 208b is, for example, a wet etching process. The liquid etchant used in the wet etching process is, for example, diluted ammonia.

A part of the substrate 200 at the exposed portion within the deep trench 206 is removed to form a bottle-shaped trench 206a. The process for removing a part of the substrate 200 at the exposed portion within the deep trench 206 is, for example, a wet etching process. The liquid etchant used in the wet etching process is, for example, ammonia, and preferably is diluted ammonia.

After forming the foregoing bottle-shaped trench 206a, the bottle-shaped trench 206a is used in subsequent processes to form the deep trench capacitor and deep trench DRAM. The person having ordinary skill in the ordinary art can know the fabrication process, and the details are not further described here.

In the embodiment, the ion implantation process is used to dope the silicon material layer 208, so as to cause the different removing rate on the silicon material layer 208. After removing the un-doped silicon material layer 208b, the property of different removing rate between the doped silicon material layer 208a and the substrate 200 is further used to remove a part of the substrate 200. As a result, the complexity of the processes for fabricating the bottle-shaped trench 206a is reduced, so that the fabrication process is simplified, the fabrication speed is improved, and the fabrication cost is reduced.

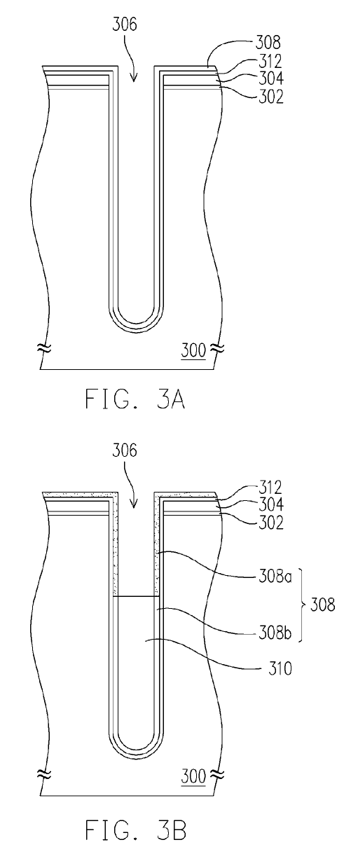

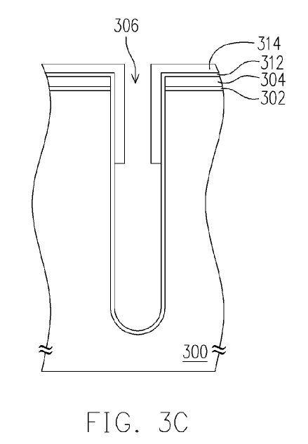

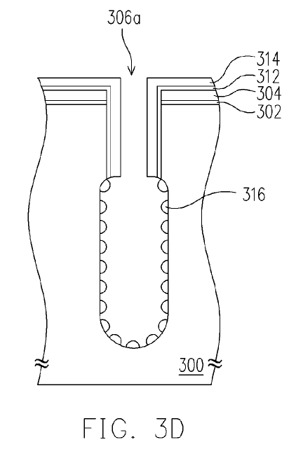

FIGS. 3A-3D are cross-sectional views, schematically illustrating a method of fabricating a bottle-shaped trench, according to another embodiment of the invention.

In FIG. 3A, a substrate 300 is provided. The substrate 300 has a deep trench 306, having already been formed. The substrate 300 is, for example, silicon substrate. The deep trench has a depth of, for example, 6-8 microns. The process to form the deep trench 306 includes, for example, sequentially forming a pad oxide layer 302 and a hard mask layer 304 over the substrate 300 in a pattern. The patterned pad oxide layer 302 and the patterned hard mask layer 304 are used as an etching mask to perform a dry etching process. The hard masking layer 304 is, for example, silicon nitride.

A conformal etching stop layer, such as silicon nitride layer 312, is formed over the substrate 300. The process for forming the silicon nitride layer 312 includes, for example, chemical vapor deposition. Before forming the conformal etching stop layer, a pad oxide layer (not shown in FIG. 3A) is preferably formed.

A conformal silicon material layer 308 is formed over etching stop layer 312, The conformal silicon material layer 308 has a thickness of, for example, 20-30 nm. The material for the silicon material layer 308 can be, for example, amorphous silicon or polysilicon. The process to form the silicon material layer 308 includes, for example, chemical vapor deposition.

In FIG. 3B, a photoresist layer 310 is formed in the deep trench 306. The photoresist layer 310 covers a portion of the silicon material layer 308. The process to form the photoresist layer 310 in the deep trench 306 is, for example, performing a spin coating process over the substrate to form a photoresist layer (not shown in FIG. 3B). Then, a dry etching process is performed to remove a portion of the photoresist layer. In addition, after forming the photoresist layer and before etching the photoresist layer, a planarization process can be further performed on the photoresist layer.

Then, the exposed portion of the silicon material layer 308, not covered by the photoresist layer 310, is performed with an ion implantation process, so that the silicon material layer 308 is divided into a doped silicon material layer 308a and an un-doped silicon material layer 308b. The ion implantation process is, for example, a tilt-angle ion implantation process. The tilt angle for the tilt-angle ion implantation process is, for example, 2-4 degrees, deviating from the normal line of the substrate surface. The preferred implantation angle can be determined, according to a depth of the silicon material layer 308 to be implanted at the portion not being covered by the photoresist layer 310 and the dimension of the opening of the deep trench 306. The ions used in the ion implantation process can include, for example, B ions or BF₂ ions. The implantation energy of the implantation process is, for example, 1 KeV-10 KeV, preferably 5 KeV. The dopant dosage for the ions in the ion implantation process can be, for example, 1×10¹³ 1/cm²-1×10¹⁷ 1/cm², and preferably 1×10¹⁵ 1/cm².

In FIG. 3C, the photoresist layer 310 is removed. The process for removing the photoresist layer 310 is, for example, a wet etching process. The inorganic solution used in the removing the photoresist layer 310 is, for example, sulfuric acid with H₂O₂ and H₂O, or the sulfuric acid with ozone and H₂O.

The silicon material layer 308b is removed to expose a portion of the silicon nitride layer 312 within the deep trench 306, wherein the removing rate on the un-doped silicon material layer 308b is greater than the removing rate on the doped silicon material layer 308a. The process to remove the un-doped silicon material layer 308b is, for example, a wet etching process. The liquid etchant used in the wet etching process is, for example, diluted ammonia.

Then, an oxidation process is performed on the doped silicon material layer 308a to change the doped silicon material layer 308a into a silicon oxide layer 314. The oxidation process performed on the doped silicon material layer 308a is, for example, thermal oxidation process. The silicon nitride layer 312 in the thermal oxidation process can sever as an oxide barrier layer, so as to prevent the covered portion of the substrate 300 from being oxidized.

Referring to FIG. 3D, the exposed silicon nitride layer 312 within the deep trench 306 is removed to expose a portion of the substrate 300. The process to remove the exposed silicon nitride layer 312 within the deep trench 306 is, for example, a wet etching with etchant, such as phosphoric acid.

Further, a part of the substrate 300 at the exposed portion within the deep trench 306 is removed to form a bottle-shaped trench 306a. The process to remove the part of the substrate 300 at the exposed portion within the deep trench 306 includes, for example, a wet etching process. The liquid etchant used in the wet etching includes, for example, ammonia, and preferably diluted ammonia.

Then, a HSG-Si layer 316 can be formed on the exposed portion of the substrate 300 within the deep trench. The process for forming the HSG-Si layer 31 6 on the exposed portion of the substrate 300 includes, for example, forming an HSG-Si layer 316 over the substrate 300, and then performing an etching back process to remove a portion of the HSG-Si layer 316 on the silicon oxide layer 314.

After forming the HSG-Si layer 316 on the exposed portion of the substrate 300, the subsequent fabrication processes to accomplish the bottle-shaped capacitor or the bottle-shaped DRAM can be known by the person having ordinary skill in the art, and then not further described here.

The invention can effectively reduce the fabrication processes for fabricating the bottle-shaped trench 306a. In addition, the structure of the bottle-shaped trench 306a can increase the surface area of the electrodes in contact with the capacitor dielectric layer therebetween for the embedded-type electrode, so as to increase the capacitance of the capacitor. On the other hand, the HSG-Si layer 316 is formed in the bottle-shaped trench 306a, and thereby can further improve capacitance.

In summary, the invention has at least the advantages as follows.

1. As proposed in the invention, the method to selectively remove material on the semiconductor substrate can be achieved by changing the removing rate for the silicon material layer.

2. As proposed in the invention for the method of fabricating a bottle-shaped trench, since the less fabrication complexity could be achieved compared to the conventional method, the fabrication processes can be reduced, the fabrication speed can be increased, and the fabrication cost can be reduced.

3. As proposed in the invention for the method of fabricating a bottle-shaped trench, the bottle-shaped trench can increase the surface area of the electrodes in contact with the capacitor dielectric layer therebetween for the embedded-type electrode, so as to further increase the capacitance of the capacitor.

4. As proposed in the invention for the method of fabricating a bottle-shaped trench, since the silicon material layer covers the pad oxide layer during the processes, it could prevent the pad oxide layer from being undesirably removed during the etching process for forming the bottle-shaped trench.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method of fabricating bottle-shaped trench, comprising:
providing a substrate, having a deep trench already being formed in the substrate;
forming a conformal silicon material layer over the substrate;
forming a masking layer in the deep trench, wherein the masking layer covers a portion of the silicon material layer;
performing an ion implantation process on the silicon material layer at a portion not being covered by the masking layer, wherein the silicon material layer is divided into a doped silicon material layer and an un-doped silicon material layer;
removing the masking layer;
removing the un-doped silicon material layer and exposing a portion of the substrate within the deep trench, wherein a removing rate of the un-doped silicon material layer is greater than a removing rate of the doped silicon material layer; and
removing a part of the substrate at the exposed portion of the substrate within the deep trench.

2. The method of claim 1, wherein the ion implantation process includes a tilt-angle implantation process.

3. The method of claim 2, wherein a tilt angle in the tilt-angle implantation process is 2-4 degrees.

4. The method of claim 1, wherein ions used in the ion implantation process include B ions or BF₂ ions.

5. The method of claim 1, wherein an energy used in the ion implantation process is 1 Kev-10 KeV.

6. The method of claim 1, wherein a dopant dosage used in the ion implantation process is 1×10¹³ 1/cm²˜1×10¹⁷ 1/cm².

7. The method of claim 1, wherein the step of removing the un-doped silicon material layer comprises a wet etching process.

8. The method of claim 7, wherein a liquid etchant used in the wet etching process includes diluted ammonia.

9. The method of claim 1, wherein the step of removing the part of the substrate at the exposed portion of the substrate within the deep trench comprises a wet etching process.

10. The method of claim 9, wherein a liquid etchant used in the wet etching process includes ammonia.

11. The method of claim 1, wherein a material for the silicon material layer includes amorphous silicon or polysilicon.

12. A method of fabricating bottle-shaped trench, comprising:
providing a substrate, having a deep trench already being formed in the substrate;
forming a conformal etching stop layer over the substrate;
forming a conformal silicon material layer over the etching stop layer;
forming a masking layer in the deep trench, wherein the masking layer covers a portion of the silicon material layer;
performing an ion implantation process on the silicon material layer at a portion not being covered by the masking layer, wherein the silicon material layer is divided into a doped silicon material layer and an un-doped silicon material layer;
removing the masking layer;
etching the un-doped silicon material layer to at least expose a portion of the etching stop layer within the deep trench, wherein a removing rate of the un-doped silicon material layer is greater than a removing rate of the doped silicon material layer;
removing the exposed portion of the etching stop layer within the deep trench; and
removing a part of the substrate at the exposed portion of the substrate within the deep trench.

13. The method of claim 12, after etching the un-doped silicon material layer, further comprising performing an oxidation process on the doped silicon material layer to change the doped silicon material layer into a silicon oxide layer.

14. The method of claim 12, wherein the ion implantation process comprises a tilt-angle ion implantation process.

15. The method of claim 14, wherein a tilt angle in the tilt-angle implantation process is 2-4 degrees.

16. The method of claim 12, wherein ions used in the ion implantation process include B ions or BF₂ ions.

17. The method of claim 12, wherein an energy used in the ion implantation process is 1 KeV-10 KeV.

18. The method of claim 12, wherein a dopant dosage used in the ion implantation process is 1×10¹³ 1/cm²-1×10¹⁷ 1/cm².

19. The method of claim 12, wherein after removing the part of the substrate at the exposed portion of the substrate within the deep trench, further comprising forming a hemispherical grain silicon (HSG-Si) layer on the exposed portion of the substrate within the deep trench.

20. The method of claim 12, an etchant used in etching the un-doped silicon material layer comprises diluted ammonia.

21. The method of claim 12, wherein the step of removing the part of the substrate at the exposed portion of the substrate within the deep trench comprises a wet etching process.

22. The method of claim 12, wherein a material for the silicon material layer includes amorphous silicon or polysilicon.
